(19) United States
(12) Patent Application Publication
(10) Pub. No.: US 2014/0083351 A1
(43) Pub. Date: Mar. 27, 2014

(54) PROCESS FOR THE GROWTH OF A CRYSTALLINE SOLID, ASSOCIATED CRYSTALLINE SOLID AND DEVICE

(71) Applicants: Jean-Christophe Chanteloup, Saclay (FR); Narine Ananyan, Erevan (AM); Vladimir Gevorgyan, Erevan (AM); Mikayel Arzakantsyan, Paris (FR)

(72) Inventors: Jean-Christophe Chanteloup, Saclay (FR); Narine Ananyan, Erevan (AM); Vladimir Gevorgyan, Erevan (AM); Mikayel Arzakantsyan, Paris (FR)

(73) Assignee: ECOLE POLYTECHNIQUE, Palaiseau (FR)

(21) Appl. No.: 14/119,619

(22) PCT Filed: May 22, 2012
(86) PCT No.: PCT/FR2012/051136

§ 371 Date: Nov. 22, 2013

(30) Foreign Application Priority Data
May 24, 2011 (FR) 11 54529

(51) Int. Cl. C30B 13/00

(52) U.S. Cl. CPC C30B 13/00
USPC 117/46; 117/220

(57) ABSTRACT

The present invention relates to a process for the growth of a crystalline solid by inching then cooling a crystallization material (2), in which the crystallization material (2) spread over a support is melted in the operating region (4) of a heat source. According to this process: outside of the operating region, the crystallization material (2) is spread over at least two areas of different compositions (3₁, 3₂, 3₃, 3₄, 3₃), and the crystallization material (2) being spread over a length greater than the length of the operating region (4), a movement of the operating region (4) relative to the crystallization material (2) is carried out so as to place successively in the operating region (4) then outside of the operating region, portions of the crystallization material of different compositions. This process is used to manufacture laser crystals having a controlled spatial distribution of doping.

### TECHNICAL FIELD

The present invention relates to a method for growing a crystalline solid, during which a crystallization material is heated until molten, then cooled in order to form a crystalline solid.

It also relates to a crystalline solid obtained by such a method and a device for implementing such a method.

Throughout the text, by “crystalline solid” is meant a monocrystalline or polycrystalline solid.

A polycrystalline solid is a solid material constituted by an assembly of a multitude of small crystals called crystallites having varied sizes and orientations, as opposed to a monocrystalline solid constituted by a single crystal.

By “crystal” is meant hereinafter a monocrystalline solid.

A crystal is a solid in which the distribution of the atoms, molecules or ions is regular and periodic in the three spatial dimensions.

A crystalline solid can for example be composed of an oxide, a silicate, a sulphide, a mixture of several of these elements.

The field of the invention is more particularly but non-limitatively that of the growth of laser crystals.

### STATE OF THE PRIOR ART

Different methods for growing a crystalline solid are known in the prior art.

All are based on the use of a starting material, called pre-melt crystallization material, deposited in the base of a crucible, melted then cooled.

The pre-melt crystallization material can be formed by:
a single crystalline solid, in particular a single crystal;
pieces of crystalline solid, in particular pieces of crystal, in the form of small pieces of centimetric size, or a mass of chips; and/or
at least one oxide powder suitable for forming a crystalline solid.

By “mass of chips” is meant a multitude of pieces of crystalline solid and in particular of pieces of crystal, of millimetric size. The term “crushing” can also be used. A person skilled in the art will preferentially use the term “crackle”.

It is possible to distinguish:
the pre-melt crystallization material, in solid phase;
the molten crystallization material, and in liquid phase after melting; and
the crystallized material, in solid phase after cooling.

The crucible is constituted by a material having a melting point substantially higher than that of the components of the pre-melt crystallization material.

These methods can be implemented in order to obtain a laser crystal, i.e. a crystal or crystalline matrix in which certain atoms are replaced by another electrically charged, optically active atom, called a “dopant ion”. The laser crystal constitutes an optical gain medium.

For example the “Bridgman horizontal” method is known. This method for growing a crystal consists of depositing the pre-melt crystallization material in a crucible, then placing the entire crucible horizontally in the hot part of a furnace. A molten crystallization material is obtained in the crucible. Then, the crucible is moved progressively laterally towards the outside of the furnace so as to cool the molten crystallization material slowly, starting from one of the ends of the crucible.

According to a variant of this method called the “temperature gradient technique” the crucible is not moved with respect to the furnace. Instead, this movement is simulated by changing the heat distribution in the hot part of the furnace.

A drawback of these methods is that a crystal is necessarily obtained the structure of which reflects the segregation coefficient k between two components of the crystallization material. This segregation coefficient k is representative of a concentration ratio of an element of the crystallization material, according to whether the crystallization material is in liquid phase (molten) or in crystallized solid phase (after melting and cooling). Reference can also be made to a solubility ratio of the element in the crystallization material, according whether said crystallization material is in liquid phase or in crystallized solid phase.

The segregation coefficient k can for example denote the ratio between the quantities of dopant (i.e. the quantities of dopant ion) present respectively in the crystallized solid phase and the liquid phase of the crystallization material. This segregation coefficient is specific to a dopant/matrix pair.

For example k has the value of approximately one for Ytterbium (Yb) in a matrix of yttrium aluminium garnet (YAG, chemical composition Y₃Al₂O₁₂). Consequently, the crystal obtained will be spatially homogeneous as regards ytterbium concentration.

For Neodymium (Nd) in a YAG matrix, k is less than one. As crystallization of the molten crystallization material proceeds, Neodymium elements are expelled into the liquid phase, which increases their concentration in the liquid phase. Consequently, the crystal obtained will be spatially non-homogeneous in Neodymium concentration.

The “Bagdasarov” method is also known in the prior art.

This method differs from the Bridgman horizontal method by the fact that the crucible is not in the furnace at the start of the process and that the size of the hot zone of the furnace is smaller than the size of the crucible. At any given moment, only the fraction of material of the crucible present in the hot part of the furnace is in liquid phase.

The method is based on the progressive movement of the crucible in the hot part of the furnace. Thus during the crystallization process, three states of the material are observed:
crystallized, at the end of the crucible leaving the furnace first (the crystallization material having crystallized after melting and cooling);
liquid, at the centre of the crucible, in the hot part of the furnace (molten crystallization material);
solid and in the form of pre-melt crystallization material, at the end of the crucible which has not yet entered the hot part of the furnace.

A drawback of this method is also that a crystal is necessarily obtained the structure of which reflects a segregation coefficient k between two components of the crystallization material.

Returning to the example of a doped crystal, when the segregation coefficient is not equal to one, the concentration of dopant material in the molten crystallization material varies at each moment with the position of the crucible in the furnace. A variation in the composition of the crystal, here its doping rate, results therefrom, as the crystal is progressively formed, starting from one end of the crucible.

This variation is not controlled, as it is defined by the segregation coefficient. In the case of Ytterbium in the YAG, as k is practically equal to one, the doping variation in the crystal removed from the crucible at the end of the process is very low (for example less than 1% difference between the maximum and minimum concentration in a Yb:YAG crystal). In contrast, for Neodymium in the YAG, a significant doping gradient can be observed. In all cases, the final doping distribution is imposed, resulting simply from the value of k.

The method described in American patent U.S. Pat. No. 5,650,008 is also known in the prior art in which an addition of matter to the molten crystallization material, progressively as the crystal forms, makes it possible to control the dopant concentration during a vertical Bridgman process.

A drawback of such a device is that it requires the implementation of a complex installation.

Another drawback of such a device is that the addition of material to the molten crystallization material creates impurities (for example gas bubbles) which degrade in particular the optical quality of the crystal obtained.

Another drawback of such a device is that it is difficult to maintain chemical equilibrium (referring to stoichiometric proportions) between different molten elements, in order to obtain the desired crystallized material.

A purpose of the present invention is to propose a method for growing a crystalline solid which does not have the drawbacks of the prior art.

In particular, a purpose of the present invention is to propose a method for growing a crystalline solid:
which allows control of the spatial distribution of a concentration of at least one element in a crystalline solid;
which makes it possible to obtain a crystalline solid of high quality, in particular optically;
which does not require a complex installation for its implementation;
the implementation of which is straightforward;

and in particular:
which makes it possible to produce a crystalline solid and more particularly a crystal having a non-monotone spatial variation in the concentration of an element;
which makes it possible to manufacture a crystalline solid and more particularly a crystal having a spatial variation in the concentration of an element, in which this element has a segregation coefficient in the crystallization material, equal to one;
which makes it possible to manufacture a crystalline solid and more particularly a crystal having no spatial variation in the concentration of an element, in which this element has a segregation coefficient in the crystallization material, different from one;

Another purpose of the present invention is to propose a crystalline solid obtained by such a method and a device specially designed for implementing such a method.

### DISCLOSURE OF THE INVENTION

This purpose is achieved with a method for growing a crystalline solid by the melting then cooling a crystallization material, in which the crystallization material distributed on a support is melted within the active region of a heat source.

According to this method:
outside the active region, at least one portion of the pre-melt crystallization material is distributed over the support, so that the whole of the crystallization material forms at least two zones having different compositions, and
since the crystallization material is distributed over a length greater than the length of the active region, the active region is moved relative to the crystallization material, so as to place portions of the crystallization material having different compositions successively in the active region, then outside the active region.

According to the invention, said method is used in order to produce laser crystals having a controlled spatial distribution of doping.

The heat source advantageously makes it possible to heat the crystallization material to the maximum melting point among one or more melting points of the components of the crystallization material.

The active region of the heat source denotes the region in which the crystallization material is molten.

Placing portions of the crystallization material having different compositions successively in the active region results in successively melting the portions of the crystallization material having different compositions.

Preferably, the crystallization material respects constraints called specific stoichiometric constraints (i.e. a chemical ratio between the components for obtaining a sought crystalline solid after cooling of the molten crystallization material).

If the stoichiometric ratio is not satisfied, the result can be that the nature of the crystalline solid obtained after cooling differs from that which was sought.

For example, it is possible to obtain a YAG crystal with yttrium oxide (Y₂O₃) and aluminium oxide (Al₂O₃) as starting oxides in a molar ratio of 3/5=60%. The stoichiometric mixture of three molecules of Y₂O₃ and five molecules of Al₂O₃ in fact gives two molecules of Y₃Al₂O₁₂. If this ratio is slightly less than 3/5, the crystal obtained will have zones in which the sought YAG will have crystallized, but also zones in which another crystal corresponding to the structure 2Y₂O₃, Al₂O₃ will have crystallized. After cooling, the crucible will thus contain a polycrystalline solid.

In contrast to certain known methods in which the whole of the crystallization material melts at the same time and is mixed for several hours using convection cells in the molten liquid, here the choice is made to melt at any moment only a portion of the crystallization material, the one subject to the active region.

The movement of the active region relative to the crystallization material combined with the fact that the length of the crystallization material is greater than the length of the active region, makes it possible for different portions of the crystallization material to be melted (in the active region) successively (in turn) then cooled for crystallization (outside the active region).

The length of the crystallization material and the length of the active region are measured in the direction of the relative movement of the active region with respect to the crystallization material.

They can correspond to the length of the projection
of the portion of crystallization material melted at a corresponding moment, and respectively
of the active region
   onto the axis of relative movement of the active region with respect to the crystallization material.

At each moment and as a result of the relative movement of the active region with respect to the crystallization material, the molten portion of the crystallization material can have a different average composition resulting from the mixing in the convection cells of elements originating from at least two contiguous zones. The average composition of the molten crystallization material is linked to the composition of the portion of crystalline solid which forms on leaving the active region.

Reference is made to the movement of the active region relative to the crystallization material:
the crystallization material can be moved within an immobile heat source;
a heat source can be moved around an immobile crystallization material;
the active region can be moved within an immobile heat source and around an immobile crystallization material (for example one resistance, then another are started successively in a furnace).

Thus it is possible to produce in a controlled way any spatial distribution whatever of concentration of at least one element in a crystalline solid, regardless in particular of a segregation coefficient value of the element in the crystallization material.

For example, it is possible to produce in a controlled way:
a crystalline solid, in particular a crystal, having a non-monotone spatial variation of concentration of an element;
a crystalline solid, in particular a crystal, having any spatial distribution of concentration of an element, for example linear, exponential, etc;
a crystalline solid in particular a crystal, having a spatial variation of concentration of an element, said element having a segregation coefficient in the crystallization material equal to one;
a crystalline solid, in particular a crystal, having no spatial variation of concentration of an element, said element having a segregation coefficient different from one;
any non-zero gradient of concentration of an element in a crystalline solid, in particular a crystal, and more specifically a doping gradient in a doped crystal.

The method according to the invention does not require the addition of material during the crystallization process, which does not involve the use of a complex and costly installation for its implementation.

The distribution of at least one portion of the crystallization material so that the whole of the crystallization material forms at least two zones having different compositions is carried out outside the active region. The crystallization material can be added to an empty support or one comprising only pre-melt crystallization material: it is thus easy to find the compositions of each element at each location, and thus to respect stoichiometric proportions, in particular in order to form a crystal (monocrystalline solid).

In the methods during which material is added to the molten phase, the injection zone causes disturbance which can promote the formation of bubbles or other diffusing particles.

In the method according to the invention, material is not added in a liquid phase of the crystallization material.

Crystalline solids can thus be obtained the spatial distribution of which is controlled and for which at least one physical or chemical property is improved.

The at least one physical or chemical property can in particular comprise an optical quality, mechanical strength, etc.

For example, a crystal can be produced for optical applications, having high optical quality. The optical quality of a crystal can be measured by the wavefront deformation of a wave passing through the crystal. A deformation is obtained for example equal to one tenth RMS (“Root Mean Square”) of the wavelength, in which the wavelength is that of the wave passing through the crystal.

Preferably, the whole of the crystallization material is distributed over the support before any portion of the mixture of the crystallization material has begun to liquefy. The solid crystallization material can be distributed over the empty support.

It can also be envisaged to distribute a portion of crystallization material when another portion of the crystallization material is already molten. It is possible in particular to add solid crystallization material to a portion of crystallization material which has not yet melted, while the crystallization process is taking place.

Preferably at least one portion of the crystallization material is distributed, by depositing it in a support formed by a crucible. The movement of the active region relative to the crystallization material then corresponds to a movement of the active region relative to the crucible.

Preferably, a movement of the active region relative to the crystallization material is carried out in a substantially horizontal plane.

The substantially horizontal plane can form an angle comprised between plus 10° and minus 10° with respect to a horizontal plane.

Keeping the crystallization material horizontal avoids a modification, under the effect of gravity, of the distribution and composition of the different zones in the crystallization material, in particular in the molten portion of the crystallization material.

Thus it is possible to achieve better control of the composition of the final crystalline solid, in particular in the case of differences of density of the different components of the pre-melt crystallization material.

The heat source advantageously consists of a crystal growth furnace, in which the heat is provided by at least one element from the following list, which is representative but non-limitative:
an electrical resistance;
a laser;
a microwave source

Provision can be made for the heat to be conveyed to the crystallization material by radiation.

It can also be envisaged that the heat is conveyed to the crystallization material by thermal conduction, for example using a crucible.

The hot part of the furnace is defined as the active region.

For example, the active region can be formed by a region of interaction between a laser beam providing heat to the furnace, and the crystallization material.

For example, the active region can be formed by a volume contained in a set of tungsten coils (electrical resistances) in which an electric current flows.

The support can consist of a crucible having in particular the shape of a rectangular parallelepiped.

The crystallization material can be distributed in a “boat-shaped” crucible i.e. the shape of a rectangular parallelepiped with the exception of a narrowed front portion.

The narrowed front portion can be terminated by a receptacle for a seed acting to initiate the growth of a crystalline solid, in particular a crystal.

This seed can be oriented along a sought crystallographic axis for the crystal that is to be grown.

This seed can be a crystal the dimensions of which are of the order of mm³.

The compositions of at least two zones can differ by a level of concentration in one or more specific chemical elements.

The compositions of the different zones advantageously have the required stoichiometric proportions for crystallizing the crystallization material, during the cooling and after melting, in order to form a desired crystalline solid. The desired crystalline solid is for example a single crystal.

Assuming a polycrystalline solid comprising crystallites of different compositions, it is possible to control the spatial distribution of the concentration of at least one given crystallite composition in a polycrystalline solid.

Such a spatial distribution is obtained by compositions of at least two zones differing by a level of concentration in one or more specific chemical elements.

For example, if yttrium oxide (Y₂O₃) and aluminium oxide (Al₂O₃) concentrations differ, according to the zones, it is possible to obtain a polycrystalline solid comprising YAG in one section and a crystal corresponding to the mixture of YAG and the structure 2Y₂O₃, Al₂O₃ in another section. It is possible for example to obtain, for an initial crystallization material distribution having:
a zone with yttrium oxide (Y₂O₃) and aluminium oxide (Al₂O₃), in a ratio of 3/5=60%, and
a zone with yttrium oxide (Y₂O₃) and aluminium oxide (Al₂O₃), in a molar ratio less than 3/5,
   a polycrystalline solid having a portion formed by a pure YAG crystal, then crystallites of YAG and of the structure 2Y₂O₃, Al₂O₃.

Provision can also be made to control the spatial distribution of the concentration of a substituted ion in a crystalline solid, and in particular in a crystal.

Preferably, the pre-melt crystallization material is formed by a crystalline matrix capable of containing substituted ions, and the compositions of the at least two zones differ only by a substituted ion concentration.

A substituted ion concentration can be zero in one zone or several.

The crystalline matrix forming the pre-melt crystallization material can be found, for each zone, in the form of several crystals of the same composition, a single crystal, oxide powders suitable for forming this crystalline matrix, etc.

The crystalline matrix is characteristic of a crystalline solid, in which certain atoms are replaced by another atom, called “substituted ion”.

There can be mentioned by way of example of a crystalline matrix capable of containing substituted ions a laser crystal the structure of which comprises “dopant ions” which are optically active, so that the laser crystal constitutes an optical gain medium.

There can also be mentioned by way of example of a substituted ion, the silver ion for improving the electrical conductivity properties of a crystal.

The substituted ions allow at least one physical or chemical property of a crystal to be modified, in particular an optical transmission quality, mechanical strength, thermal conductivity, electrical conductivity, etc.

Using the method according to the invention, said physical or chemical property can be modified locally.

A laser crystal can for example be produced having a predetermined doping profile, for example in order to obtain a constant temperature over the whole of the laser crystal despite non-homogeneous cooling or non-homogeneous pumping distribution.

It is thus possible to reduce the internal stresses in the laser crystal, which improves the quality of the laser beam produced or amplified by the laser crystal but also extends the life span of said crystal.

Moreover, a controlled doping profile can make it possible to:
increase a quantity of energy capable of being extracted or amplified from the laser crystal in the form of a laser beam, for a given volume of said crystal;
limit energy losses due to transversal oscillations.

According to a particularly advantageous embodiment, the pre-melt crystallization material is formed by a crystalline matrix of yttrium aluminium garnet (YAG) capable of containing dopant ions, and the compositions of the at least two zones differ only by the Ytterbium (Yb) dopant ion concentration.

This concentration can be zero in at least one zone.

The YAG has the advantage in particular of having a high thermal conductivity. This is an advantageous material for producing a laser crystal.

Advantageously, the pre-melt crystallization material in each zone is in the form of a powder and/or a mass of chips, and:
at least one impervious surface is positioned in order to delimit a boundary between two adjacent zones;
the pre-melt crystallization material is distributed over the support, on each side of the impervious surface; and
the impervious surface is removed.

By “impervious surface” is meant an element forming a boundary between two adjacent zones, impervious to the pre-melt crystallization material.

The impervious surface is advantageously positioned so that it does not form a plane parallel to an axis of movement of the active region relative to the crystallization material.

The impervious surface is advantageously positioned so that the molten portion of the crystallization material has an average composition which is modified over time.

Clear boundaries can thus easily be produced between zones having different compositions.

Clear boundaries between the different zones of different compositions facilitate calculation, making it possible to link a distribution of pre-melt crystallization material, and a spatial distribution of an element in the crystalline solid obtained.

Moreover, a pre-melt crystallization material, in the form of a powder or a mass of chips offers great freedom in the design of the different zones, hence the same freedom in the design of the crystalline solid obtained by the method according to the invention.

The pre-melt crystallization material in each zone can also be presented in the form of a single crystal per zone.

The speed of movement of the crystallization material relative to the active region can be less than 1 centimetre per hour.

This speed is for example comprised between 0.5 millimetre per hour and 3 millimetres per hour.

Under the action of heat, convection cells form in the molten crystallization material.

These convection cells gradually make the molten mixture homogeneous.

Such a speed allows good homogenization of the molten crystallization material.

Thus, the average composition of the molten crystallization material corresponds to the composition at any point of the molten crystallization material, giving high predictability of the spatial distribution of the concentration of at least one element, in the final crystalline solid.

Preferably, the movement of the active region relative to the crystallization material is continuous.

The movement of the active region relative to the crystallization material is advantageously implemented until the whole of the crystallization material has left the active region.

The method according to the invention advantageously comprises a final step of removing a sample of crystalline solid, from a crude crystalline solid obtained after cooling.

The method according to the invention can be used to produce laser crystals (monocrystalline solids) having a controlled spatial distribution of doping.

By “controlled” is meant that this spatial distribution of doping can be easily calculated (and therefore predicted) from knowledge of the compositions and distributions of the zones of the crystallization material.

The invention also relates to a crystalline solid obtained by the method according to the invention.

The invention relates in particular to a monocrystalline solid (or crystal) obtained by the method according to the invention.

The invention also relates to a device for implementing the method according to the invention, comprising:
a heat source having an active region for melting a crystallization material,
a support for receiving the crystallization material, and
means for moving the support relative to the active region.

In this device, the length of the support is greater than the length of the active region, and the device comprises means for depositing crystallization material on the support and at the entry to the active region, in the portion of the crystallization material which has not yet started to melt.

The lengths of the support and of the active region are measured as explained above, with reference to the lengths of the crystallization material and of the active region.

The aforementioned details of the heat source, the active region, the support, and the crystallization material, can equally relate to the device according to the invention.

This device is particularly suitable for the variant embodiment of the method according to the invention, according to which crystallization material is added during the crystallization process, to the portion of crystallization material which has not yet started to melt.

In the method and the device according to the invention, the crystalline solid is preferably a crystal (monocrystalline solid).

### DESCRIPTION OF THE FIGURES AND EMBODIMENTS

Other advantages and characteristics of the invention will become apparent on examination of the detailed description of embodiments which are in no way limitative, and the attached diagrams, in which:

FIG. 1 shows a mode of implementation of the method according to the invention;

FIG. 2 shows a device specifically designed for implementing the method according to the invention;

FIG. 3 shows an example of the length of the crystallization material and of the active region;

FIGS. 4A and 4B show a second embodiment of a method according to the invention, and a spatial distribution of the concentration of an element in the crystal obtained;

FIGS. 5A and 5B show a third embodiment of a method according to the invention, and a spatial distribution of the concentration of an element in the crystal obtained;

FIG. 6 shows an experimental result of spatial distribution of the concentration of an element in a crystal obtained by the method according to the invention;

FIG. 7 shows an example of spatial distribution of the concentration of an element in a crystal obtained by the method according to the invention; and

FIG. 8 shows a type of crucible which may be used in the method according to the invention.

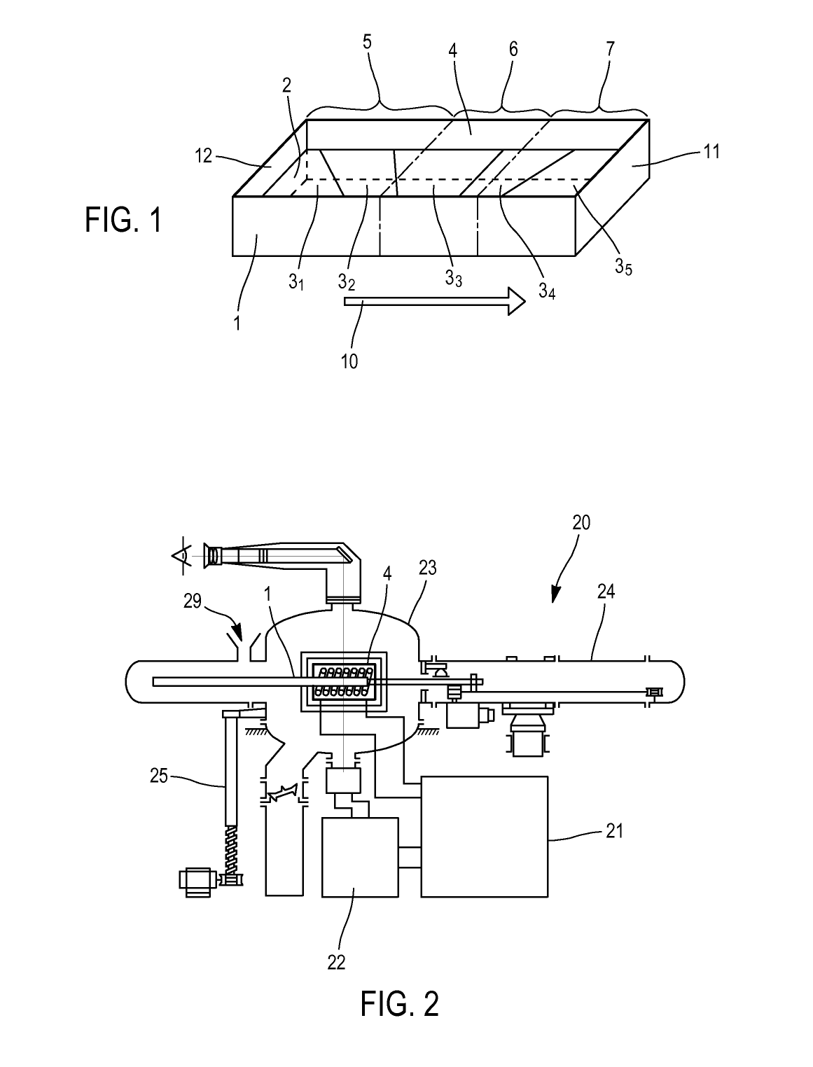

Firstly there will be described, with reference to FIG. 1, a first mode of implementation of the method according to the invention.

According to this method, a crucible 1 is filled with a crystallization material 2.

During this step of filling the crucible 1, the crystallization material 2 is distributed in the crucible 1 in at least two zones (here five zones) 3₁, 3₂, 3₃, 3₄, and 3₅ of different compositions.

The crystallization material 2 is for example formed by cracked crystal called “crackle”.

This “crackle” is produced by cracking a crystal or several crystals by thermal shock.

The limit between two secant zones can be delimited for example by placing in the empty crucible 1 at least one blade (plastic, paper, card, etc) oriented along an axis having at least one component orthogonal to the plane of the base of the crucible. The crucible 1 is then filled with different compositions of crystallization material on either side of each blade, then the blades are removed.

However, it is not necessary to establish a clear separation between the at least two zones.

Then one end 11 of the crucible 1 is introduced into the active region of a heat source.

Provision can also be made to place a portion of the crucible 1 in a region which is then activated to become the active region of a heat source. This embodiment is particularly advantageous in the event the crucible 1 is “boat shaped”, i.e. a rectangular parallelepiped with the exception of a narrowed front portion in which a seed can be placed. Such a crucible 1 is shown in perspective view in FIG. 8. In order to avoid melting said seed, the crucible is initially placed so that the seed is located outside the active region.

The portion of crystallization material situated in the active region is melted.

The temperature in the active region is higher than the highest melting point of the component(s) of the (pre-melt) crystallization material.

This temperature is for example 2000° C.

The crucible 1 is moved progressively with respect to the fixed active region 4, along an axis of movement 10.

In this example, said movement is linear.

The portion of the crucible introduced first into the active region also leaves this active region first.

This portion is then subjected to a temperature slightly below the melting point of the molten crystallization material. The temperature difference with the temperature in the active region is for example of the order of 100° C.

It cools on leaving the active zone in order to form a crystalline solid.

There are then three different phases in the crucible 1:
a portion 5 which has not yet been subjected to the action of the active region 4 (this active region is shown in FIG. 1 enclosed between two dash-dotted lines), and which is therefore still in a cracked form;
a portion 6 which is in the active region 4, portion 6 then being in liquid form;
a portion 7 which has already emerged from the active region 4, forming a crystalline solid.

The crucible 1 is moved with respect to the active region 4 until its other end 12 along the axis of movement 10 leaves the active region 4.

The action of the heat zone can also be modified by progressively decreasing its temperature, in order to solidify the last portion of the crystallization material to be melted.

The different zones 3₁, 3₂, 3₃, 3₄, and 3₅ of the crystallization material 2 are distributed so that at least one boundary between two adjacent zones is secant with the axis of movement 10.

Moreover, the length of the active region 4 along the axis of movement 10 is less than the length of the crucible along the axis of movement 10.

In this way, the average composition of the portion 6 is modified during the movement of the crucible 1.

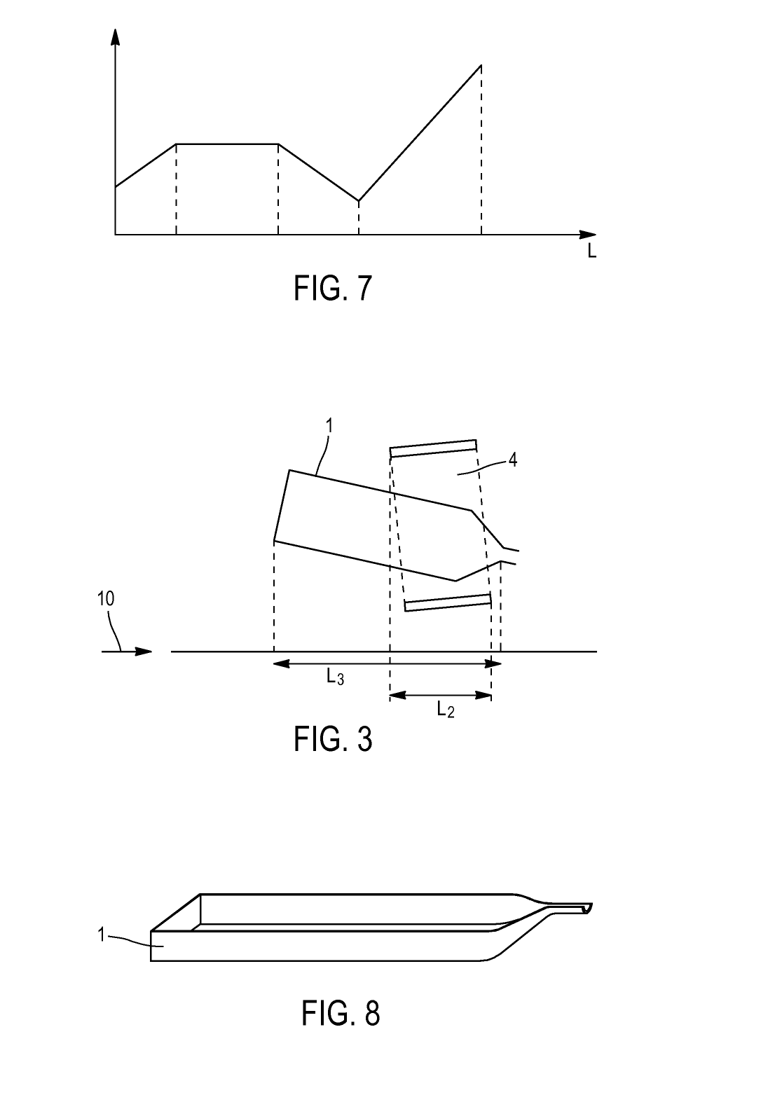

FIG. 3 shows a method of measuring the length of the active region 4 and that of the crucible 1.

The length of the active region 4 corresponds to the length L₂ of the projection of the active region 4 on the axis of movement 10.

The length of the crucible 1 corresponds to the length L₃ of the projection of the crucible 1 (in particular the portion of the crucible which is in the active region 4 at a given moment during the implementation of the method according to the invention) on the axis of movement 10.

FIG. 2 shows a device 20 for growing a crystalline solid, specifically designed for implementing the method according to the invention;

The device 20 comprises resistance heating coils surrounding a crystallization material, and forming an active region.

The effective length of the active region 4 also depends on the temperature close to these heating resistances and on a speed of relative movement of the heating resistances with respect to the crystallization material.

The active region 4 is connected to a supply 21 for the heating resistances. The supply 21 is itself connected to a control and stabilization unit 22.

The active region 4 is situated in a dome 23, in which the desired conditions, in particular pressure and atmospheric conditions, can be established. For example, the gas composition in the dome 23 comprises at least one gas chosen from nitrogen, helium and argon.

The dome 23 is borne by vibration dampers 25.

The crucible 1 contains crystallization material, and moves on a belt (not shown) with respect to the active region 4, in the direction of an inlet chamber 24.

The crucible 1 is made from molybdenum and is up to 40 mm high for example.

Preferably, the portion 6 of molten crystallization material 2 is distributed according to a cylindrical volume the base of which is broad with respect to the height in order to facilitate the evaporation of certain impurities. The ratio of said base to the square of said height is for example greater than one.

The width of the crucible 1 depends on the space available in the active region (here, between the heating resistances).

Its length is for example 180 mm, this value being non-limitative.

The assembly formed by the heating resistances and the dome 23 forms a furnace of the “Sapfir-2MG” type. Such a furnace comprises only a heat source (the heating resistances) and means for moving an active region of the heat source relative to the crystallization material.

The crucible 1 remains horizontal throughout its relative movement with respect to the active region 4.

This movement has a speed of approximately 2 millimetres per hour. Thus, at each moment, the molten portion 6 constitutes a homogeneous mix since convection cells in the liquid have sufficient time before the mix crystallizes to homogenize the molten portion 6 by their movement.

FIG. 2 shows means 29 for depositing crystallization material in the crucible 1 and at the entry to the active region 4.

These means 29 are optional, according to whether:
the distribution of the crystallization material is prepared before any melting process, or
crystallization material is added during the crystallization process, to the portion of crystallization material which has not yet started to melt.

From the crystalline solid obtained a sample can be cut that has the particular dimensions sought and a substantially constant purity over the whole of its volume:

The crystalline solid has for example:
a height of 4 mm;
a length of 40 mm; and
a width of 12 mm.

The sample has for example:
a height of 2.9 mm;
a length of 25 mm; and
a width of 10 mm.

Such a sample can be used in an optical system, in particular as an optical gain medium.

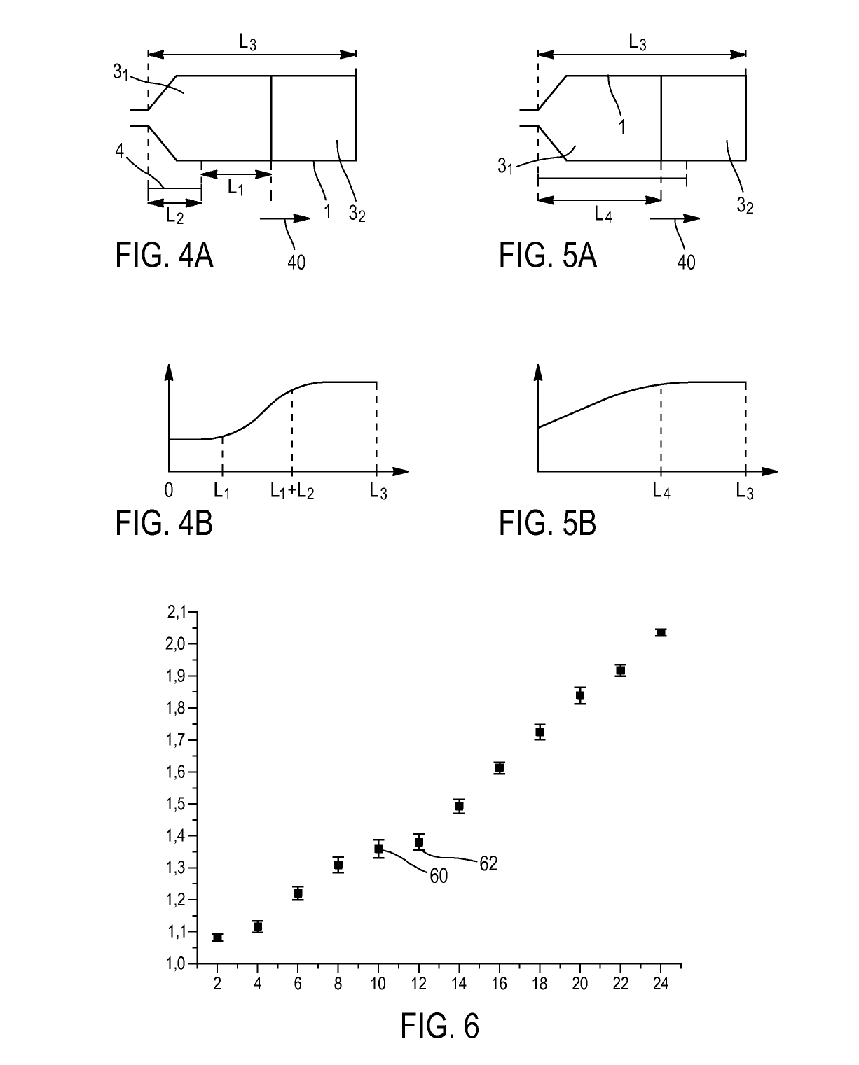

Two embodiments of a method according to the invention, and the spatial distributions of concentration of an element in a monocrystalline solid (crystal) obtained, will be described as follows with reference to FIGS. 4A, 4B, 5A and 5B.

The spatial distributions of concentration are parallel to the growth planes of the crystal, i.e. perpendicular to the axis of movement 10.

FIG. 4A shows a bottom view of a boat-shaped crucible 1, in which the crystallization material 2 is initially distributed.

In this example, the crystallization material comprises two zones 3₁, 3₂ having different compositions.

The compositions of the different zones are obtained in the following manner:
for each zone, a Yb:YAG crystal (Ytterbium-doped yttrium aluminium garnet), is previously formed, each one having a given constant ytterbium concentration, and starting from a mixture having stoichiometric proportions of yttrium oxide (Y₂O₃), ytterbium oxide (Yb₂O₃) and aluminium oxide (Al₂O₃);
each crystal is then cracked into pieces of millimetric size in order to form a “crackle” which will be deposited in the corresponding zone.

For example, in zone 3₁ there is 20 at. % of ytterbium, and in zone 3₂, 50 at. % of ytterbium.

The abbreviation “at. %” denotes an atomic percentage. Here, this is a percentage of the yttrium atoms replaced by one ytterbium atom.

Stoichiometric proportions must be respected so that yttrium atoms are replaced by ytterbium atoms in a YAG matrix.

Of course, these examples are non-limitative and as many zones can be provided as desired, for example three zones with respectively 0 at. % of ytterbium, 20 at. % of ytterbium and 50 at. % of ytterbium.

The arrow 40 denotes the direction of movement of the active region 4 relative to the immobile crucible 1.

In FIG. 4A, the length L₂ of the active region 4 is less than the length {L₁+L₂} of zone 3₁.

The length of the active region 4 can tend to change during the method according to the invention. This can be explained by the fact that the crystal produced has a greater thermal transfer capacity than that of the pre-melt crystallization material. The length of the active region 4 can be kept constant by adjusting its temperature.

FIG. 4B represents the spatial distribution of concentration of ytterbium ions in the crystal obtained by the method according to the invention, and under conditions such as shown in FIG. 4A.

The x-axis corresponds to a spatial position on the length of the crystal obtained.

The y-axis corresponds to the atomic percentage of ytterbium ions.
From 0 to L₁ (wherein L₁ is the difference in absolute value between the length of the active region 4 and the length of zone 3₁), the concentration of ytterbium ions in the crystal obtained is equal to 20 at. % because the active region covers only zone 3₁;
from L₁ to {L₁+L₂}, the concentration of ytterbium ions in the crystal obtained varies from 20 at. % (concentration in zone 3₁) to a concentration called the final concentration comprised between 20 and 50 at. % (concentration in zone 3₂), because the active region 4 covers a width of zone 3₂ that becomes gradually larger, until covering only zone 3₂;
from {L₁+L₂} to L₃ which is the length of the crucible 1, the concentration of ytterbium ions in the crystal obtained is practically constant and equal to said final concentration because the active region covers only zone 3₂.

The segregation coefficient k can also play a role in the method according to the invention, although this is not the case in the example shown, as it is equal to one as stated in the introduction.

FIG. 5A differs from FIG. 4A only in that the length of the active region 4 is greater than the length L₄ of zone 3₁.

FIG. 5B differs from FIG. 4B in that it comprises only two portions:
from 0 to L₄, the concentration of ytterbium ions in the crystal obtained varies from a value greater than 20 at. % (average concentration in the portion of the crucible 1 covered by the active region 4) to a concentration called the final concentration comprised between the previous average value and 50 at. % (concentration in zone 3₂), because the active region 4 covers a relative width of zone 3₂ that becomes gradually larger, until covering only zone 3₂;
from L₄ to L₃ which is the length of the crucible 1, the concentration of ytterbium ions in the crystal obtained is practically constant and equal to said final concentration because the active region covers only zone 3₂.

It is clear therefore that, using the method for growing a crystal according to the invention, it is possible to obtain any spatial distribution whatever of the concentration of an element in a crystal, in particular a dopant ion.

FIG. 6 shows an experimental result of spatial distribution of the concentration of an element in a crystal obtained by the method according to the invention.

The x-axis corresponds to a position in millimetres on a crystal obtained.

The y-axis corresponds to an atomic percentage of ytterbium ions in a YAG matrix.

The points 60 represent experimental measurements.

In order to obtain them, slices were cut from the crystal produced, in a plane orthogonal to the direction of relative movement of the active region with respect to the crystallization material.

The concentration in ytterbium ions was then calculated by measuring the light absorption of the slice.

The points 60 are shown each associated with a bar 62 which represents uncertainty with respect to the measurement of the concentration in ytterbium ions.

It is thus clear that implementing the method according to the invention makes it possible to produce a spatial distribution of doping according to a variable profile.

A variation of the spatial distribution of dopant ions in a laser crystal makes it possible to reach a constant temperature in the whole of the laser crystal even when it is heated or cooled in a non-homogeneous manner.

For example, a Yb:YAG crystal is produced with a thickness of 7.5 mm and having a doping gradient ranging from 1.3 at. % to 2.3 at. %.

Thus, the stored energy density in the crystal is constant when it is:
pumped at 10 Hz, on a single pumping face, and at 14 kW/cm², and
cooled on the pumping face by an air stream at 295.15 K (degrees Kelvin) and on the opposite face by a flow of water at 288 K.

Thus the internal stresses in the crystal are reduced, which increases its life span and improves the quality of the laser beam obtained.

Moreover, such a doping gradient makes it possible to reduce energy losses due to the transverse oscillations known as ASE for “amplified spontaneous emission”.

Investment in the optically pumped power of the laser crystal can thus be limited.

Moreover, such a doping gradient makes it possible to increase the quantity of energy that can be extracted from the laser crystal per unit of volume.

The crystal described above, having a thickness of 7.5 mm, makes it possible to extract as much energy as a similar crystal but with a constant doping at 1.3 at. % and thickness of 1.15 cm.

It is clear therefore that it is possible to limit the weight of the laser installations in order to obtain a given energy of the laser beam.

Moreover, the crystal described above makes it possible to extract as much energy as a similar crystal of the same thickness but with a constant doping at 1.9 at. %. Such a crystal with a constant doping at 1.9 at. % has the drawback of high energy losses due to transverse oscillations, unlike the crystal described above, and having a non-zero doping gradient.

FIG. 7 shows an example of a spatial distribution of the concentration of an element in a crystal obtained by the method according to the invention.

The x-axis corresponds to a spatial position on the length of the crystal obtained.

The y-axis corresponds to a concentration of said element in the crystal obtained.

FIG. 7 shows the great flexibility offered by the method according to the invention for obtaining all kinds of spatial distributions.

Of course, the invention is not limited to the examples which have just been described, and numerous adjustments can be made to these examples without departing from the scope of the invention.

In particular any shapes of zones and any compositions of zones forming the crystallization material can be envisaged.

Provision can also be made for any type of relative movement of the active region with respect to the crystallization material, for example movement in a curve.

It is possible to obtain any concentration profile whatever of a given element in a crystalline solid, in particular profiles having successively a positive slope and a negative slope which hitherto could not be obtained.

1. A method for growing a crystalline solid by melting then cooling a crystallization material, in which the crystallization material distributed over a support is melted in the active region of a heat source, comprising the following steps:
distributing at least one portion of the pre-melt crystallization material over the support, outside the active region, so that the whole of the crystallization material forms at least two zones having different compositions,
as the crystallization material is distributed over a length greater than the length of the active region, moving the active region relative to the crystallization material, so as to place portions of the crystallization material having different compositions successively in the active region, then outside the active region, and
producing laser crystals having a controlled spatial distribution of doping.

2. Method according to claim 1, wherein moving the active region (4) relative to the crystallization material is carried out in a substantially horizontal plane.

3. Method according to claim 1, wherein the crystallization material is distributed in a “boat-shaped” crucible having the shape of a rectangular parallelepiped with a narrowed front portion.

4. Method according to claim 1, wherein:
the pre-melt crystallization material is formed by a crystalline matrix capable of containing substituted ions, and
the compositions of the at least two zones differ only by a substitute ion concentration.

5. Method according to claim 1, wherein:
the pre-melt crystallization material is formed by a crystalline matrix of yttrium aluminium garnet capable of containing dopant ions, and
the compositions of the at least two zones differ only by a ytterbium dopant ion concentration.

6. Method according to claim 1, wherein the pre-melt crystallization material in each zone is in the form of a powder and/or a mass of chips, and wherein the method further comprises:
positioning at least one impervious surface to delimit a boundary between two adjacent zones;
distributing the pre-melt crystallization material over the support, on each side of the impervious surface; and
removing the impervious surface.

7. Method according to claim 1, wherein a speed of movement of the crystallization material relative to the active region is less than 1 centimeter per hour.

8. Method according to claim 1, wherein the movement of the active region relative to the crystallization material is continuous.

9. Method according to claim 1, wherein the movement of the active region relative to the crystallization material is implemented until the whole of the crystallization material has left the active region.

10. A device for implementing the method according to claim 1, comprising:
a heat source having an active region for melting a crystallization material,
a support for receiving the crystallization material,
means for moving the support relative to the active region, the length of the support being greater than the length of the active region, and
means for depositing crystallization material on the support and at an entry to the active region, in a portion of the crystallization material which has not yet started to melt.
